(19) United States
(12) Patent Application Publication
(10) Pub. No.: US 2024/0213307 A1
(43) Pub. Date: Jun. 27, 2024

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Tomohiro MORIYA, Matsumoto-city (JP); Akimasa KINOSHITA, Matsumoto-city (JP)

(73) Assignee: FUJI ELECTRIC CO., LTD., Kawasaki-shi (JP)

(21) Appl. No.: 18/427,607

(22) Filed: Jan. 30, 2024

Related U.S. Application Data
(63) Continuation of application No. PCT/JP2022/047790, filed on Dec. 23, 2022.

(30) Foreign Application Priority Data
Feb. 2, 2022 (JP) 2022-015237

(51) Int. Cl. H01L 29/06; H01L 21/02; H01L 21/04; H01L 29/16; H01L 29/423

(52) U.S. Cl. CPC H01L 29/06; H01L 21/02378; H01L 21/02529; H01L 21/046; H01L 29/1608; H01L 29/4236

(57) ABSTRACT

A p-type impurity concentration profile in a depth direction of a p-type base region is adjusted by two or more stages of ion implantation to the p-type base region. The two or more stages of ion implantation are each set to have a mutually different acceleration voltage and a dose amount that is lower the higher is the acceleration voltage. The p-type impurity concentration profile is asymmetrical about a depth position of a highest impurity concentration and the impurity concentration decreases from this depth position in a direction to n+-type source regions and in a direction to an n+-type drain region. In the p-type impurity concentration profile, the impurity concentration decreases, forming a step at one or more different depth positions closer to the n+-type drain region than is the depth position of the highest impurity.

### CROSS REFERENCE TO RELATED APPLICATIONS

This is a continuation application of International Application PCT/JP2022/047790 filed on Dec. 23, 2022 which claims priority from a Japanese Patent Application No. 2022-015237 filed on Feb. 2, 2022, the contents of which are incorporated herein by reference.

### BACKGROUND OF THE INVENTION

### 1. Field of the Invention

Embodiments of the invention relate to a semiconductor device and a method of manufacturing a semiconductor device.

### 2. Description of the Related Art

Conventionally, in a metal oxide semiconductor field effect transistor (MOSFET) having an insulated gate with a metal-oxide film-semiconductor three-layer structure, when the gate threshold voltage is increased to suppress erroneous turn-on due to noise, there is a tradeoff in that the on-resistance increases and to improve this tradeoff relationship, the cell structure is optimized (a cell being a constituent unit of a device).

In general, in a silicon carbide (SiC)-MOSFET having a trench gate structure employing SiC as a semiconductor material, to improve the tradeoff relationship in which the on-resistance decreases when the gate threshold voltage is increased, a predetermined gate threshold voltage is maintained while the on-resistance is reduced by decreasing the cell size, optimally designing a junction FET (JFET) portion, etc.

Optimally designing the JFET portion means inhibiting depletion of the JFET portion during switching from an off-state to an on-state and suppressing increases in JFET resistance, for example, by increasing the impurity concentration of the JFET portion, increasing a width of the JFET portion, etc. The JFET portion is an n-type region adjacent to a channel portion in a vicinity of a bottom of a trench (gate trench) and constitutes a current path of a main current.

FIG. 6 is a cross-sectional view of a structure of a conventional semiconductor device. A conventional semiconductor device 110 depicted in FIG. 6 is a vertical SiC-MOSFET that has a semiconductor substrate 130 containing SiC as a semiconductor material, and a trench gate structure at a front surface of the semiconductor substrate 130. The semiconductor substrate 130 is formed by sequentially stacking epitaxial layers 132, 133 constituting, respectively, an n⁻-type drift region 102 and a p-type base region 103 on an n⁺-type starting substrate 131 constituting an n⁺-type drain region 101.

The semiconductor substrate 130 has, as the front surface, a main surface having the p-type epitaxial layer 133 and, as a back surface, a main surface having the n⁺-type starting substrate 131. The p-type epitaxial layer 133 is doped with a p-type impurity such as aluminum (Al). The trench gate structure is configured by the p-type base region 103, n⁺-type source regions 104, p⁺⁺-type contact regions 105, trenches 106, gate insulating films 107, and gate electrodes 108.

The n⁺-type source regions 104 and the p⁺⁺-type contact regions 105 are diffused regions formed in the p-type epitaxial layer 133 by implanting ions in the p-type epitaxial layer 133 from the front surface of the semiconductor substrate 130.

The n⁺-type source regions 104 and the p⁺⁺-type contact regions 105 are selectively formed between the front surface of the semiconductor substrate 130 and the p-type base region 103 and are in contact with the p-type base region 103.

A portion of the p-type epitaxial layer 133 excluding the n⁺-type source regions 104 and the p⁺⁺-type contact regions 105 constitutes the p-type base region 103. The trenches 106 penetrate through the n⁺-type source regions 104 and the p-type base region 103 from the front surface of the semiconductor substrate 130 in a depth direction and terminate in the n⁻-type epitaxial layer 132. In the trenches 106, the gate electrodes 108 are provided via the gate insulating films 107.

In the p-type base region 103, at portions thereof (hereinafter, “channel portions” depicted as portions each surrounded by dashed line) 103a along sidewalls of the trenches 106, a channel (n-type inversion layer) is formed when the MOSFET is in the on-state. A p-type impurity such as aluminum (Al) is introduced in the p-type base region 103 by one stage (one session) of ion implantation from the front surface of the semiconductor substrate 130 to adjust a resistance value of the channel portions 103a.

The gate threshold voltage and the on-resistance are determined by the acceleration voltage and dose amount of this one stage of ion implantation to the p-type base region 103. A p-type impurity concentration profile 141 (refer to later-described FIG. 3) of the p-type base region 103 in a depth direction exhibits a Gaussian distribution in which a peak concentration is at a depth position of a range of the one stage of ion implantation in the p-type base region 103; and from a depth position D101 of the peak concentration, the impurity concentration decreases by substantially a same gradient in a direction to the n⁺-type source regions 104 and as that in a direction to the n⁺-type drain region 101.

Between the p-type base region 103 and the n⁻-type drift region 102, at depth positions closer to the n⁺-type drain region 101 than are bottoms of the trenches 106, p⁺-type regions 121, 122 and an n-type current spreading region 123 are each selectively provided. The p⁺-type regions 121, 122 and the n-type current spreading region 123 are diffused regions formed in the n⁻-type epitaxial layer 132 by ion implantation.

The p⁺-type regions 121, 122 have a function of mitigating electric field applied to the gate insulating films 107 at the bottoms of the trenches 106. Between the p⁺-type regions 121, 122 that are adjacent to each other in a direction parallel to the front surface of the semiconductor substrate 130 is the n-type JFET portion that constitutes a current path of a drift current (main current) that flows in the semiconductor substrate 130, from a drain electrode 112 to a source electrode 111 when the MOSFET is in the on-state.

As for a conventional vertical SiC-MOSFET with a trench gate structure, a device has been proposed in which a p-type base region is constituted by only a p-type epitaxial layer (for example, refer to Japanese Laid-Open Patent Publication No. 2020-191420). In Japanese Laid-Open Patent Publication No. 2020-191420, no ion implantation of a p-type impurity is performed in the p-type base region. Therefore, the impurity concentration of the p-type base region is uniform and no concentration gradient occurs in the p-type impurity concentration profile in the depth direction of the p-type base region.

As for another conventional vertical SiC-MOSFET with a planar type structure, a device has been proposed in which in a p-type base region, a shallow portion thereof close the front surface of the semiconductor substrate is formed by only a p-type epitaxial layer while a deep portion thereof farther from the front surface of the semiconductor substrate is formed in an n⁻-type epitaxial layer beneath the p-type epitaxial layer by ion implantation of a p-type impurity (for example, refer to Japanese Laid-Open Patent Publication No. 2018-206873).

In Japanese Laid-Open Patent Publication No. 2018-206873, in the p-type base region, the impurity concentration of the shallow portion thereof close to the front surface of the semiconductor substrate is lower than the impurity concentration of the deep portion thereof farther from the front surface of the semiconductor substrate. In the p-type base region, punch-through is suppressed by making the impurity concentration of the deep portion, which is farther from the front surface of the semiconductor substrate, relatively high while channel mobility is increased by making the impurity concentration of the shallow portion, which is close to the front surface of the semiconductor substrate, relatively low.

Further, as another conventional vertical SiC-MOSFET with a trench gate structure, a device has been proposed in which a p-type impurity is introduced in a p-type base region by two stages of ion implantation of mutually differing acceleration voltages, thereby, forming a high-concentration implanted region of a p-type (for example, refer to Japanese Patent No. 6115678). In Japanese Patent No. 6115678, the high-concentration implanted region is formed in the p-type base region, whereby the on-resistance may be reduced without changing the gate threshold voltage or variation of the gate threshold voltage.

In Japanese Patent No. 6,115,678, a p-type impurity concentration profile in the depth direction of the high-concentration implanted region exhibits, for each of the two stages of ion implantation of differing acceleration voltages, a peak concentration at the depth position of the respective range thereof; and between the peak concentrations, the impurity concentration decreases by a gradient forming a curve that is recessed toward an n⁺-type drain region, in the shape of a valley (curve that is convex in a direction in which the impurity concentration decreases).

### SUMMARY OF THE INVENTION

According to an embodiment of the present invention, a semiconductor device includes: a semiconductor substrate containing silicon carbide and having a first main surface and a second main surface opposite to each other; a first semiconductor region of a first conductivity type, provided in the semiconductor substrate; a second semiconductor region of a second conductivity type, provided between the first main surface of the semiconductor substrate and the first semiconductor region; a third semiconductor region of the first conductivity type, selectively provided between the first main surface of the semiconductor substrate and the second semiconductor region; a trench penetrating through the third semiconductor region and the second semiconductor region, and reaching the first semiconductor region; a gate electrode provided in the trench via a gate insulating film; a first electrode electrically connected to the second semiconductor region and the third semiconductor region; and a second electrode provided at the second main surface of the semiconductor substrate. The second semiconductor region has an impurity concentration profile in a depth direction from the first main surface to the second main surface. In in the impurity concentration profile: an impurity concentration of the second semiconductor region decreases by a first gradient in the depth direction from a first depth position of a highest impurity concentration to the first main surface, the impurity concentration decreases monotonically in the depth direction from the first depth position to the second main surface and the impurity concentration profile exhibits a step-shaped curve at one or more different second depth positions closer to the second main surface than is the first depth position, and the impurity concentration, from the first depth position to the one or more different second depth positions, decreases by a second gradient that is more gradual than the first gradient.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to an embodiment.

FIG. 2 is an enlarged cross-sectional view of a vicinity of a channel portion in FIG. 1.

FIG. 3 is a characteristics diagram depicting impurity concentration profiles along cutting line A-A′ in FIG. 2.

FIG. 4 is a characteristics diagram depicting ion implantation profiles of the channel portion depicted in FIG. 1.

FIG. 5 is a characteristics diagram depicting a relationship between gate threshold voltage and on-resistance of first and second examples.

FIG. 6 is a cross-sectional view of a structure of a conventional semiconductor device.

### DETAILED DESCRIPTION OF THE INVENTION

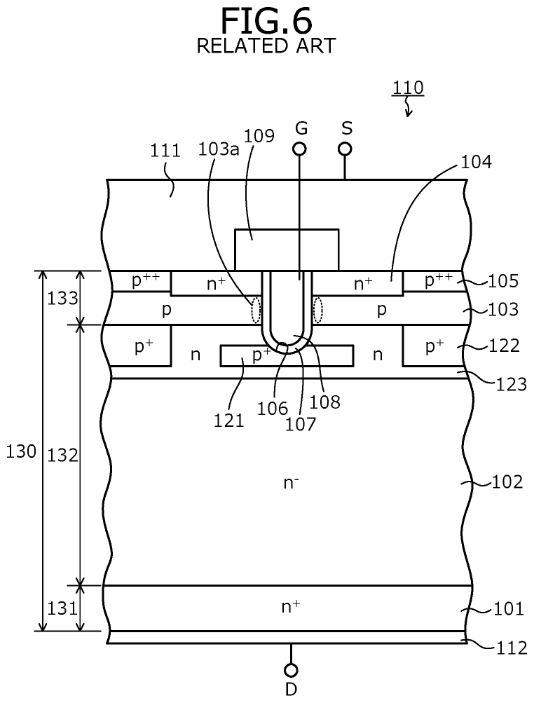

First, problems associated with the conventional techniques are discussed. In the conventional semiconductor device 110 described above (refer to FIG. 6), reduction of the cell size is limited by manufacturing process limitations due to processing accuracy and thus, reduction of the on-resistance by reducing the cell size is limited. Further, when the on-resistance is reduced by increasing the width (interval between the p⁺-type regions 121, 122 that are adjacent to each other) of the JFET portion, a saturation current value increases and short-circuit capability decreases. The short-circuit capability is a capability to withstand a short-circuit current. A short-circuit current is a current that flows between a drain and source during a load short-circuit or an alarm short-circuit and becomes a large current exceeding the rated current. The saturation current value is the saturation value of current between the drain and source dependent on and determined by the voltage between a gate and the source.

Embodiments of a semiconductor device and method of manufacturing a semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

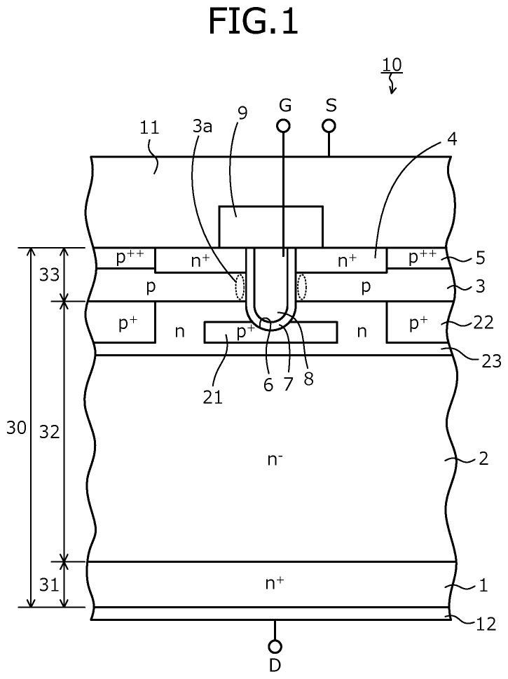

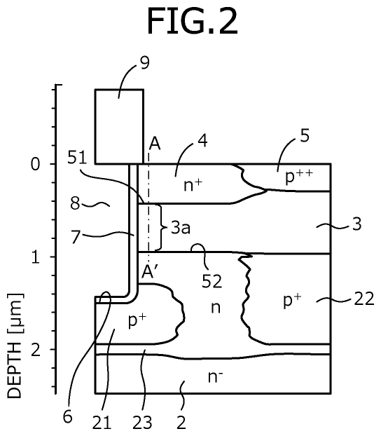

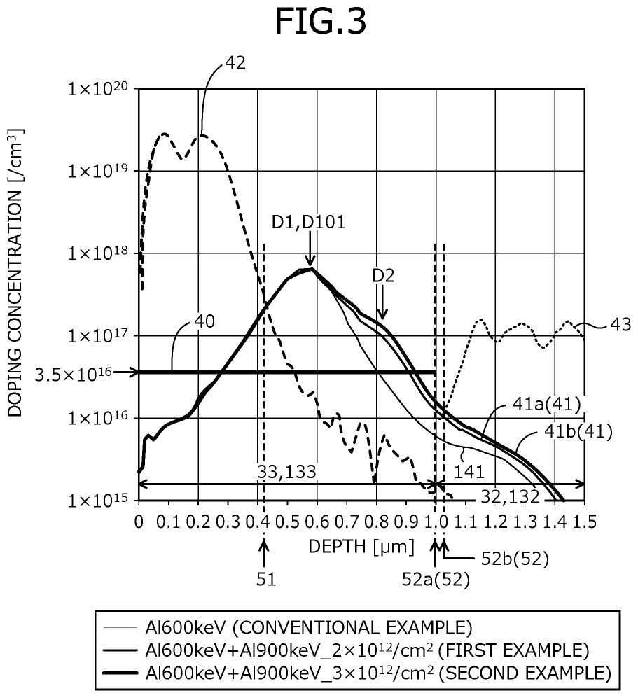

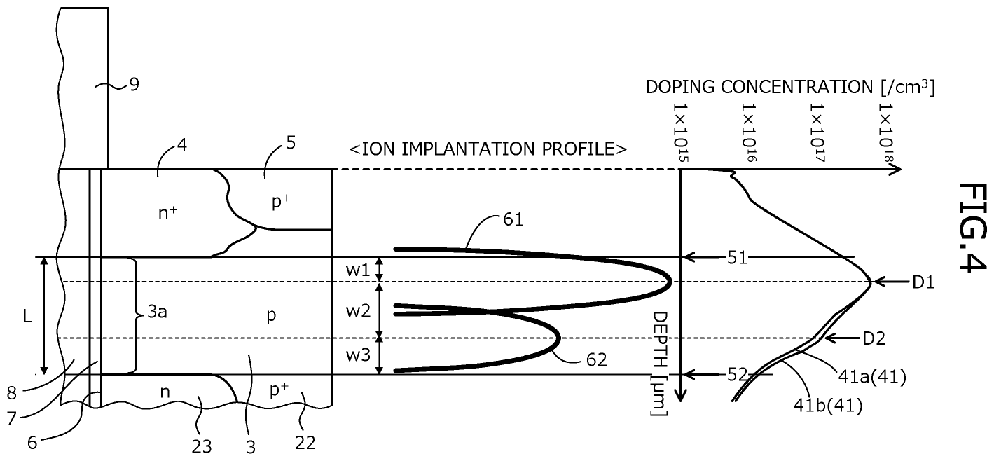

A structure of a semiconductor device according to an embodiment is described. FIG. 1 is a cross-sectional view depicting the structure of the semiconductor device according to the embodiment. FIG. 2 is an enlarged cross-sectional view of a vicinity of a channel portion in FIG. 1. FIG. 3 is a characteristics diagram depicting impurity concentration profiles along cutting line A-A′ in FIG. 2. FIG. 4 is a characteristics diagram depicting ion implantation profiles of the channel portion depicted in FIG. 1. A semiconductor device 10 according to the embodiment depicted in FIG. 1 is a vertical SiC-MOSFET having a semiconductor substrate (semiconductor chip) 30 containing silicon carbide (SiC) as a semiconductor material, and a trench gate structure in the semiconductor substrate 30, at a front surface of the semiconductor substrate 30.

The semiconductor substrate 30 is an epitaxial substrate in which epitaxial layers (silicon carbide layers) 32, 33 constituting an n⁻-type drift region 2 (first semiconductor region) 2 and a p-type base region (second semiconductor region) 3 are stacked sequentially, in the order stated, on a front surface of an n⁺-type starting substrate 31 containing SiC as a semiconductor material. The semiconductor substrate 30 has, as the front surface, a main surface (first main surface) having the p-type epitaxial layer (second-conductivity-type silicon carbide layer) 33 and, as a back surface (back surface of the n⁺-type starting substrate 31), a main surface (second main surface) having the n⁺-type starting substrate 31. The n⁻-type epitaxial layer (first-conductivity-type silicon carbide layer) 32, for example, is doped with an n-type impurity such as nitrogen (N). The p-type epitaxial layer 33, for example, is doped with a p-type impurity such as aluminum (Al).

The n⁺-type starting substrate 31 constitutes an n⁺-type drain region 1. The n⁻-type drift region 2 is adjacent to the n⁺-type starting substrate 31 in the depth direction. The p-type base region 3 is provided between the front surface of the semiconductor substrate 30 and the n⁻-type drift region 2. The trench gate structure is configured by the p-type base region 3, n⁺-type source regions (third semiconductor regions) 4, p⁺⁺-type contact regions 5, trenches 6, gate insulating films 7, and gate electrodes 8. Between the p-type base region 3 and the n⁻-type drift region 2, p⁺-type regions (first and second high-concentration regions) 21, 22 and an n-type current spreading region 23 are each selectively provided at deep positions closer to the n⁺-type drain region 1 (back surface of the semiconductor substrate 30) than are bottoms of the trenches 6.

The p⁺-type regions 21, 22 and the n-type current spreading region 23 are diffused regions formed in the n⁻-type epitaxial layer 32 by ion implantation. The p⁺-type regions 21 are provided apart from the p-type base region 3 and face the bottoms of the trenches 6 in the depth direction. The p⁺-type regions 21, by non-depicted portions thereof, are partially connected to the p⁺-type regions 22 or are connected to other p-type regions and are thereby electrically connected to a source electrode 11. The p⁺-type regions 21, may be in contact with the gate insulating films 7 at the bottoms of the trenches 6 or may be apart from the bottoms of the trenches 6.

Preferably, the p⁺-type regions 21 may face bottom corner portions (borders between the bottom and sidewalls) of the trenches 6 in the depth direction. As a result, electric field applied to the gate insulating films 7 at the bottom corner portions of the trenches 6 is mitigated and the electric field mitigation effect in a vicinity of the bottoms of the trenches 6 increases. The p⁺-type regions 22 are provided between the trenches 6 that are adjacent to one another; the p⁺-type regions 22 are apart from the trenches 6 and the p⁺-type regions 21. Each of the p⁺-type regions 22, at a surface thereof facing the n⁺-type source regions 4 (the front surface of the semiconductor substrate 30), is in contact with the p-type base region 3 and is electrically connected to the source electrode 11 via the p-type base region 3.

The p⁺-type regions 21, 22 are adjacent to one another in a direction parallel to the front surface of the semiconductor substrate 30. Between the p⁺-type regions 21, 22 is an n-type JFET portion formed adjacent to the later-described channel portions 3a on a current path of a drift current (main current) that flows in the semiconductor substrate 30, in a direction from a drain electrode 12 to the source electrode 11. Respective surfaces of the p⁺-type regions 21, 22 facing the n⁺-type drain region 1 are positioned at substantially a same depth. Substantially the same depth means the same depth within a range that includes allowable error due to process variation.

The n-type current spreading region 23 is a so-called current spreading layer (CSL) that reduces carrier spreading resistance. The n-type current spreading region 23 is provided between the trenches 6, which are adjacent to one another, and is in contact with the p⁺-type regions 21, 22. Further, the n-type current spreading region 23, at a surface thereof facing the n⁺-type source regions 4, is in contact with the p-type base region 3 while at surface thereof facing the n⁺-type drain region 1, is in contact with the n⁻-type drift region 2 and in a direction parallel to the front surface of the semiconductor substrate 30, extends to the trenches 6 and is in contact with the gate insulating films 7.

The n-type current spreading region 23 may be omitted. In an instance in which the n-type current spreading region 23 is omitted, instead of the n-type current spreading region 23, the n⁻-type drift region 2 passes between the trenches 6 that are adjacent to one another and reaches the p-type base region 3 from the n⁺-type drain region 1 and in a direction parallel to the front surface of the semiconductor substrate 30, extends to the trenches 6 and is in contact with the gate insulating films 7. A portion of the n⁻-type epitaxial layer 32 excluding the p⁺-type regions 21, 22 and the n-type current spreading region 23 constitutes the n⁻-type drift region 2.

The n⁺-type source regions 4 and the p⁺⁺-type contact regions 5 are diffused regions formed in the p-type epitaxial layer 33 by implanting ions in the p-type epitaxial layer 33 from the front surface of the semiconductor substrate 30. The n⁺-type source regions 4 and the p⁺⁺-type contact regions 5 are selectively provided between the front surface of the semiconductor substrate 30 and the p-type base region 3 and are in contact with the p-type base region 3. The n⁺-type source regions 4 and the p⁺⁺-type contact regions 5 are in ohmic contact with the source electrode 11, at the front surface of the semiconductor substrate 30.

The n⁺-type source regions 4 are provided closer to the trenches 6 than are the p⁺⁺-type contact regions 5 and are in contact with the gate insulating films 7 at the sidewalls of the trenches 6. The p⁺⁺-type contact regions 5 may be omitted. In an instance in which the p⁺⁺-type contact regions 5 are omitted, instead of the p⁺⁺-type contact regions 5, the p-type base region 3 reaches the front surface of the semiconductor substrate 30 and is in contact with the source electrode 11. A portion of the p-type epitaxial layer 33 excluding the n⁺-type source regions 4 and the p⁺⁺-type contact regions 5 constitutes the p-type base region 3.

The trenches 6 penetrate through the n⁺-type source regions 4 and the p-type base region 3 in the depth direction from the front surface of the semiconductor substrate 30 and terminate in the n⁻-type epitaxial layer 32. The gate insulating films 7 are provided along inner walls of the trenches 6. In the trenches 6, the gate electrodes 8 are provided on the gate insulating films 7. The gate electrodes 8 face the n⁺-type source regions 4, the p-type base region 3, and the n-type current spreading region 23 (in an instance in which the n-type current spreading region 23 is not provided, the n⁻-type drift region 2), via the gate insulating films 7 at the sidewalls of the trenches 6.

At portions (“channel portions”, in the drawings, portions surrounded by dashed line) 3a of the p-type base region 3 along the sidewalls of the trenches 6, a channel (n-type inversion layer) is formed when the MOSFET is in the on-state. In the p-type base region 3, a p-type impurity such as aluminum (Al) is introduced by two or more stages (two or more sessions) of ion implantation from the front surface of the semiconductor substrate 30. By the two or more stages (in FIGS. 3 and 4, for example, two stages) of ion implantation performed to the p-type base region 3, a p-type impurity concentration profile 41 in the depth direction of the p-type base region 3 is optimized and the resistance value of the channel portions 3a is adjusted.

For the two or more stages of ion implantation performed to the p-type base region 3, mutually different acceleration voltages are set and the dose amount is set to be lower the higher is the acceleration voltage. Thus, the two or more stages of ion implantation performed to the p-type base region 3 exhibit relatively low peak concentrations of the impurity at deep depth positions close to the n⁺-type drain region 1 the higher is the acceleration voltage thereof and the two or more stages of ion implantation form ion implantation profiles (correspond to ion implantation profiles 61, 62 in FIG. 4) that exhibit Gaussian distribution in which, from the depth positions, the impurity concentration decreases by substantially a same gradient in a direction to the n⁺-type source regions 4 and in a direction to the n⁺-type drain region 1.

Conditions of each of the two or more stages of ion implantation to the p-type base region 3 are set relative to the conditions of the stage having the next lower acceleration voltage; for example, when the acceleration voltage and the dose amount are set for a stage, the acceleration voltage is set to be within a range of about 1.3 times to 1.6 times that of the stage having the next lower acceleration voltage, and the dose amount of is set to be within a range of about 10% to 20% of that of the stage having the next lower acceleration voltage. In particular, when the acceleration voltage of a predetermined stage of ion implantation is 600 keV and the dose amount is about 1.5×10¹³/cm², for example, for the ion implantation with the next higher acceleration voltage, the acceleration voltage thereof is set to be within a range of about 780 keV to 960 keV and the dose amount thereof is set to be within a range of about 1.5×10¹²/cm² to 3.0×10¹²/cm².

The p-type impurity concentration profile 41 in the depth direction of the p-type base region 3 exhibits peak concentrations in the ion implantation profiles at depth positions (correspond to depth positions D1, D2 in FIG. 3) of the respective ranges of the two or more stages of ion implantation having mutually differing acceleration voltages; and the peak concentrations are relatively lower the closer is the position thereof to the n⁺-type drain region 1. The depth position (first depth position: corresponds to the depth position D1 in FIG. 3) of the peak concentration in the ion implantation profile of the ion implantation having the lowest acceleration voltage of the two or more stages of ion implantation to the p-type base region 3 may be set so that the impurity concentration of the p-type base region 3 is highest closer to the n⁺-type source regions 4 than at a center of the p-type base region 3 in the depth direction.

In the p-type impurity concentration profile 41 in the depth direction of the p-type base region 3, the impurity concentration decreases in a direction to the n⁺-type source regions 4 from the depth position of the peak concentration (peak concentration occurring closest to the n⁺-type source regions 4) in the ion implantation profile of the ion implantation with the lowest acceleration voltage. In the p-type impurity concentration profile 41 in the depth direction of the p-type base region 3, an ion implantation profile for a portion closer to the n⁺-type source regions 4 than is the depth position of the peak concentration occurring closest to the n⁺-type source regions 4 is an ion implantation profile for a portion closer to the n⁺-type source regions 4 than is the depth position of the peak concentration in the ion implantation profile of the ion implantation with the lowest acceleration voltage.

In the p-type impurity concentration profile 41 in the depth direction of the p-type base region 3, a p-type impurity concentration profile for a portion closer to the n⁺-type drain region 1 than is the depth position (in FIG. 3, corresponds to the depth position D1) of the peak concentration occurring closest to the n⁺-type source regions 4 is formed by the impurity concentration profile of the p-type epitaxial layer 33 and an ion implantation profile of a portion closer to the n⁺-type drain region 1 than is the depth position of the peak concentration in the ion implantation profile of the ion implantation with the lowest acceleration voltage and an ion implantation profile of the ion implantation of a remaining portion of the two or more stages of ion implantation performed to the p-type base region 3. The impurity concentration profile of the p-type epitaxial layer 33 is uniform in the depth direction and thus, the p-type impurity concentration profile 41 in the depth direction of the p-type base region 3 is asymmetrical about the depth position of the peak concentration occurring closest to the n⁺-type source regions 4.

In the p-type impurity concentration profile 41 in the depth direction of the p-type base region 3, from the depth position of the peak concentration occurring closest to the n⁺-type source regions 4, the impurity concentration decreases in a direction to the n⁺-type drain region 1, forming a step at each depth position (second depth position) of each range of each stage of ion implantation excluding the stage of ion implantation with the lowest acceleration voltage. In the p-type impurity concentration profile 41 in the depth direction of the p-type base region 3, an ion implantation profile for a portion closer to the n⁺-type drain region 1 than is the depth position of the peak concentration occurring closest to the n⁺-type drain region 1 is an ion implantation profile for a portion closer to the n⁺-type drain region 1 than is the depth position of the peak concentration of the ion implantation profile with the highest acceleration voltage.

Furthermore, in the p-type impurity concentration profile 41 in the depth direction of the p-type base region 3, between peak concentrations of ion implantation profiles adjacent to each other in the depth direction, in a direction to the n⁺-type drain region 1, the impurity concentration decreases by a gradient resulting in a curve that protrudes in a mountain-like shape (a curve convex in a direction in which the impurity concentration increases) or the impurity concentration is uniform (a flat curve without a gradient). In other words, in the p-type impurity concentration profile 41 in the depth direction of the p-type base region 3, no valley-shaped depression (convex in a direction in which the impurity concentration decreases) occurs between peak concentrations of ion implantation profiles adjacent to each other in the depth direction.

In the p-type impurity concentration profile 41 in the depth direction of the p-type base region 3, the peak concentration occurring closest to the n⁺-type source regions 4 is in a range of, for example, about 4.0×10¹⁷/cm³ to 8.0×10¹⁷/cm³. In the p-type impurity concentration profile 41 in the depth direction of the p-type base region 3, the depth position of the peak concentration occurring closest to the n⁺-type source regions 4 is set to be closer to the n⁺-type drain region 1 than are the n⁺-type source regions 4. In other words, in the p-type impurity concentration profile 41 in the depth direction of the p-type base region 3, a distance w1 from the depth position D1 of the peak concentration occurring closest to the n⁺-type source regions 4, to a border 51 between any one of the n⁺-type source regions 4 and the p-type base region 3 is greater than 0 μm.

The distance w1 is, for example, about 10% to 30% of a channel length L (10%≤w1/L×100≤30%). The channel length L is a length of the channel portions 3a along the sidewalls of the trenches 6 and is a distance between the border 51 between any one of the n⁺-type source regions 4 and the p-type base region 3 and a border 52 between the p-type base region 3 and the n-type current spreading region 23. A distance (corresponds to a distance w2 depicted in FIG. 4) between the peak concentrations of the ion implantation profiles adjacent to each other in the depth direction in the p-type impurity concentration profile 41 in the depth direction of the p-type base region 3 is within a range of about 0.1 μm to 0.2 μm between all the peak concentrations.

A distance (corresponds to a distance w3 depicted in FIG. 4) from the depth position (corresponds to the depth position D2 in FIG. 4) of the peak concentration occurring closest to the n⁺-type drain region 1 in the p-type impurity concentration profile 41 in the depth direction of the p-type base region 3 to the border 52 between the p-type base region 3 and the n-type current spreading region 23 may be, preferably, as wide as possible. In the p-type impurity concentration profile 41 in the depth direction of the p-type base region 3, the closer that the depth position of the peak concentration closest to the n⁺-type drain region 1 is to the n-type current spreading region 23, the higher is the impurity concentration of the p-type base region 3 closer to the n⁺-type drain region 1 and the distance between any one of the channel portions 3a and a nearest one of the p⁺-type regions 21 decreases, whereby the resistance of the current path of the drift current increases.

In particular, for example, as described above, in the conventional semiconductor device 110 (refer to FIG. 6l; hereinafter, “conventional example”), the p-type impurity concentration profile 141 in the depth direction of the p-type base region 103 is adjusted by one stage of ion implantation to the p-type base region 103. The p-type impurity concentration profile 141 in the depth direction of the p-type base region 103 exhibits a peak concentration at the depth position of the range of the one stage of ion implantation to the p-type base region 103 and exhibits Gaussian distribution in which the impurity concentration decreases from the depth position D101 of the peak concentration by a substantially same gradient in a direction to the n⁺-type source regions 104 and in a direction to the n⁺-type drain region 101 (refer to FIG. 3).

In other words, the p-type impurity concentration profile 141 in the depth direction of the p-type base region 103 of the conventional example is symmetrical about the depth position D101 of the peak concentration of the ion implantation profile of the one stage of ion implantation and it is impossible to adjust only one side of the p-type impurity concentration profile (one side among the n⁺-type drain region 101 side and the n⁺-type source regions 104 side sandwiching the depth position D101). Conditions of the one stage of ion implantation performed to the p-type base region 103 of the conventional example depicted in FIG. 3 are an acceleration voltage of about 600 keV, a dopant of aluminum, and a dose amount of about 1.5×10¹³/cm² (in FIG. 3, indicated as “Al600keV”).

On the other hand, with respect to the semiconductor device 10 according to the embodiment (hereinafter, first and second examples), in the p-type impurity concentration profile 41 in the depth direction of the p-type base region 3, the n⁺-type drain region 1 side (one side) bordered by the depth position D1 of the peak concentration of the ion implantation profile of the ion implantation with the lowest acceleration voltage may be adjusted independently. For example, to easily compare the first and second examples with the conventional example, of the two stages of ion implantation performed to the p-type base region 3 of the first and second examples, conditions of the first stage of the ion implantation (the first stage having the lowest acceleration voltage) are assumed to be the same as those of the one stage of ion implantation in the conventional example (in FIG. 3, indicated as “Al600keV”).

Conditions of the remaining one stage of the ion implantation (hereinafter, the second stage of the ion implantation) of the two stages of the ion implantation performed to the p-type base region 3 of the first example are assumed to be, for example, an acceleration voltage of about 900 keV, a dopant of aluminum, and a dose amount of about 2.0×10¹²/cm² (in FIG. 3, indicated as “+Al900keV_2×10¹²/cm²”). Conditions of the second stage of the ion implantation of the second example are assumed to be, for example, an acceleration voltage of about 900 keV, a dopant of aluminum, and a dose amount of about 3.0×10¹²/cm² (in FIG. 3, indicated as “+Al900keV_3×10¹²/cm²”). Other than the different dose amount in the second stage of the ion implantation performed to the p-type base region 3, the first and second examples are fabricated under the same conditions.

In the first and second examples, the respective p-type impurity concentration profiles 41 (41a, 41b) thereof in the depth direction of the respective p-type base regions 3 thereof each exhibits a peak concentration at the depth position D1 that is the same as the depth position D101 of the peak concentration in the p-type impurity concentration profile 141 of the conventional example as a result of the ion implantation profile 61 of the first stage of the ion implantation being performed under the same ion implantation conditions as those of the conventional example. In addition, the respective p-type impurity concentration profiles 41 (41a, 41b) in the depth direction of the respective p-type base regions 3 each exhibits a peak concentration in the ion implantation profile 62 of the second stage of the ion implantation at the depth position D2 closer to the n⁺-type drain region 1 than is the depth position D1 of the peak concentration occurring closest to the n⁺-type source regions 4.

As a result, in the p-type impurity concentration profile 41 (41a, 41b) in the depth direction of the p-type base region 3, the p-type impurity concentration in an entire area closer to the n⁺-type drain region 1 than is the depth position D1 of the peak concentration occurring closest to the n⁺-type source regions 4 is higher than the p-type impurity concentration of a portion closer to the n⁺-type drain region 101 than is the depth position D101 of the peak concentration in the p-type impurity concentration profile 141 of the conventional example. Further, in the p-type impurity concentration profile 41 (41b) in the depth direction of the p-type base region 3, the higher is the dose amount of the second stage of the ion implantation, the higher is the p-type impurity concentration closer to the n⁺-type drain region 1 than is the depth position D1 of the peak concentration occurring closest to the n⁺-type source regions 4.

In FIG. 3, in the p-type impurity concentration profile 41 in the depth direction of the p-type base region 3, the peak concentration occurring closest to the n⁺-type source regions 4 is, for example, about 6.0×10¹⁷/cm³. An intersection between an n-type impurity concentration profile 42 in the depth direction of the n⁺-type source regions 4 and the p-type impurity concentration profile 41 in the depth direction of the p-type base region 3 is the border 51 between any one of the n⁺-type source regions 4 and the p-type base region 3. An intersection of the p-type impurity concentration profile 41 (41a, 42b) in the depth direction of the p-type base region 3 and an n-type impurity concentration profile 43 in the depth direction of the n-type current spreading region 23 is the border 52 (52a, 52b) between the p-type base region 3 and the n-type current spreading region 23.

The n-type impurity concentration profile 42 in the depth direction of each of the n⁺-type source regions 4 exhibits a peak concentration at a depth position apart from the front surface of the semiconductor substrate 30, and exhibits substantially Gaussian distribution in which the impurity concentration decreases from the depth position of the peak concentration in a direction to the front surface of the semiconductor substrate 30 and in a direction from the depth position of the peak concentration to the n⁺-type drain region 101. The n-type impurity concentration profile 42 in the depth direction of each of the n⁺-type source regions 4 may have two or more locations where substantially a same peak concentration occurs as a result of the two or more stages of ion implantation having substantially a same dose amount and mutually differing acceleration voltages. In this instance, the curve between the peak concentrations in the n-type impurity concentration profile 42 in the depth direction of each of the n⁺-type source regions 4 may form a valley-shaped depression (be convex in a direction in which the impurity concentration decreases).

The n-type impurity concentration profile 43 in the depth direction of the n-type current spreading region 23 is a box profile formed by multiple stages of ion implantation of substantially a same dose amount and mutually differing acceleration voltages and has locations where substantially a same peak concentration occurs as a result of the multiple stages of ion implantation, the number of said locations being equal to the number of stages of ion implantation. The curve between the peak concentrations in the n-type impurity concentration profile 43 in the depth direction of the n-type current spreading region 23 may form a valley-shaped depression. Substantially the same (or a substantially uniform) impurity concentration and substantially the same dose amount mean, respectively, the same impurity concentration and the same dose amount within a range that includes allowable error due to process variation.

In particular, the n-type impurity concentration profile 43 in the depth direction of the n-type current spreading region 23 has a wave-like shape in which ion implantation profiles having a Gaussian distribution shape are connected in a depth direction Z and in which the depth position of the range of each of the multiple stages of the ion implantation is assumed as a peak concentration and the impurity concentration decreases from the depth position of each of the peak concentrations in a direction to the n⁺-type source regions 4 and in a direction to the n⁺-type drain region 1. In the n-type impurity concentration profile 43 in the depth direction of the n-type current spreading region 23, the impurity concentration may decrease from the depth position of the peak concentration occurring closest to the n⁺-type source regions 4, in a direction to the n⁺-type source regions 4.

A portion from the border 51 between any one of the n⁺-type source regions 4 and the p-type base region 3 to the border 52 (52a, 52b) between the p-type base region 3 and the n-type current spreading region 23 constitutes one of the channel portions 3a of the p-type base region 3. In a p-type impurity concentration profile 40 in the depth direction of the p-type epitaxial layer 33, the impurity concentration is uniform and, for example, is about 3.5×10¹⁶/cm³. The p-type impurity concentration profile 41 described above may be formed by only the channel portions 3a of the p-type base region 3 and a portion excluding the channel portions 3a of the p-type base region 3 may be configured by only the p-type epitaxial layer 33 to form the p-type impurity concentration profile that is uniform in the depth direction.

The on-resistance is determined by the peak concentration occurring closest to the n⁺-type source regions 4 in the p-type impurity concentration profile 41 in the depth direction of the p-type base region 3. The gate threshold voltage is determined by the peak concentration occurring closest to the n⁺-type source regions 4 in the p-type impurity concentration profile 41 in the depth direction of the p-type base region 3 and the impurity concentration of a portion of the p-type base region 3 close to the n⁺-type drain region 1 (portion thereof closer to the n⁺-type drain region 1 than is the depth position of the peak concentration occurring closest to the n⁺-type source regions 4). The higher is the impurity concentration of the portion of the p-type base region 3 close to the n⁺-type drain region 1, the higher is the gate threshold voltage and the noise tolerance is enhanced, whereby erroneous turning on of the MOSFET may be suppressed. Further, when large current flows, internal resistance of the portion of the p-type base region 3 close to the n⁺-type drain region 1 is small and thus, even when the gate threshold voltage is high, the on-resistance may be maintained.

Further, the p-type impurity concentration profile 41 in the depth direction of the p-type base region 3 gradually decreases from the depth position of the peak concentration occurring closest to the n⁺-type source regions 4, in a direction to the n⁺-type drain region 1, whereby even when the gate threshold voltage value is high, variation of the gate threshold voltage with respect to a targeted gate threshold voltage value may be maintained. The impurity concentration of the p-type base region 3, in a portion thereof from the depth position of the peak concentration occurring closest to the n⁺-type source regions 4 in the p-type impurity concentration profile 41 in the depth direction, to a depth position (third depth position), for example, about 0.2 μm in a direction to the n⁺-type drain region 1, may be preferably, for example, about at least 1/10 of the peak concentration occurring closest to the n⁺-type source regions 4.

An interlayer insulating film 9 is provided in an entire area of the front surface of the semiconductor substrate 30 and covers the gate electrodes 8. In FIG. 1, while only a single cell (constituent unit of a device) of the MOSFET is depicted, in the semiconductor substrate 30, multiple cells each having the same structure are disposed adjacently. In contact holes of the interlayer insulating film 9, the n⁺-type source regions 4 and the p⁺⁺-type contact regions 5 (in an instance in which the p⁺⁺-type contact regions 5 are omitted, the p-type base region 3) are exposed.

The source electrode (first electrode) 11 is in ohmic contact with the front surface of the semiconductor substrate 30 in the contact holes of the interlayer insulating film 9 and is electrically connected to the n⁺-type source regions 4, the p⁺⁺-type contact regions 5, and the p-type base region 3. The drain electrode 12 is provided in an entire area of the back surface of the semiconductor substrate 30. The drain electrode (second electrode) 12 is in ohmic contact with and electrically connected to the n⁺-type drain region 1 (the n⁺-type starting substrate 31).

Operation of the semiconductor device 10 according to the embodiment is described. When voltage less than the gate threshold voltage is applied to the gate electrodes 8 while voltage (forward voltage) that is positive with respect to the source electrode 11 is applied to the drain electrode 12, pn junctions (main junctions) between the p⁺-type regions 21, 22, the p-type base region 3, the n-type current spreading region 23, and the n⁻-type drift region 2 are reverse biased, whereby the SiC-MOSFET (the semiconductor device 10) maintains the off-state.

On the other hand, when voltage is applied in a forward direction between a source and drain and voltage at least equal to the gate threshold voltage is applied to the gate electrodes 8, a channel (n-type inversion layer) is formed in the channel portions 3a of the p-type base region 3 along the sidewalls of the trenches 6. As a result, current (drift current) flows from the n⁺-type drain region 1, along the channel portions 3a to the n⁺-type source regions 4 and the SiC-MOSFET turns on.

A portion of the p-type base region 3 close to the n⁺-type drain region 1 has an internal resistance that is lower than that of a portion having the peak concentration occurring closest to the n⁺-type source regions 4 in the p-type impurity concentration profile 41 in the depth direction of the p-type base region 3. During initial switching from off to on of the SiC-MOSFET, even the portion of the p-type base region 3 close to the n⁺-type drain region 1 bears voltage and thus, the gate threshold voltage is determined by the impurity concentration of the portion of the p-type base region 3 close to the n⁺-type drain region 1.

The greater is the thickness (in FIG. 4, corresponds to a sum of the distances w2, w3) of the portion of the p-type base region 3 close to the n⁺-type drain region 1, the greater is the load of the voltage on the portion of the p-type base region 3 close to the n⁺-type drain region 1. As a result, during the initial switching from off to on of the SiC-MOSFET, the voltage load on the portion having the peak concentration occurring closest to the n⁺-type source regions 4 in the p-type impurity concentration profile 41 in the depth direction of the p-type base region 3 may be reduced.

When the SiC-MOSFET turns on completely, the internal resistance of the portion of the p-type base region 3 close to the n⁺-type drain region 1 contributes minimally and only the portion having the peak concentration occurring closest to the n⁺-type source regions 4 in the p-type impurity concentration profile 41 in the depth direction of the p-type base region 3 bears the voltage. Therefore, the on-resistance is determined by the peak concentration occurring closest to the n⁺-type source regions 4 in the p-type impurity concentration profile 41 in the depth direction of the p-type base region 3.

Further, the p-type impurity concentration profile 41 in the depth direction of the p-type base region 3 gradually decreases from the depth position of the peak concentration occurring closest to the n⁺-type source regions 4, in a direction to the n⁺-type drain region 1. Thus, even when the impurity concentration is increased and the gate threshold voltage is increased in the portion of the p-type base region 3 close to the n⁺-type drain region 1, variation of the gate threshold voltage with respect to the targeted gate threshold voltage value may be maintained.

Next, a method of manufacturing the semiconductor device 10 according to the embodiment is described. First, at the front surface of the n⁺-type starting substrate (starting wafer) 31 containing SiC as a semiconductor material, the n⁻-type epitaxial layer 32 constituting the n⁻-type drift region 2 is epitaxially grown (deposited). At this time, the n⁻-type epitaxial layer 32 is epitaxially grown having a thickness that is thinner than a predetermined thickness of the product (the semiconductor device 10) after completion. The impurity concentration of the n⁻-type epitaxial layer 32 is, for example, about 1×10¹⁶/cm³.

Next, by photolithography and ion-implantation of a p-type impurity, the p⁺-type regions 21 and lower portions (portions facing the n⁺-type drain region 1) of the p⁺-type regions 22 are each selectively formed in surface regions of the n⁻-type epitaxial layer 32 so as to repeatedly alternate with one another. Further, by photolithography and ion-implantation of an n-type impurity, in surface regions of the n⁻-type epitaxial layer 32, a lower portion of the n-type current spreading region 23 is formed between the p⁺-type regions 21 and the p⁺-type regions 22 adjacent to one another.

Next, epitaxial growth is further performed thereby increasing the thickness of the n⁻-type epitaxial layer 32 to the predetermined thickness. Next, by photolithography and ion-implantation of a p-type impurity, upper portions (portions facing the n⁺-type source regions 4) of the p⁺-type regions 22 are selectively formed in the portion increasing the thickness of the n⁻-type epitaxial layer 32. Further, by photolithography and ion-implantation of an n-type impurity, in the portion increasing the thickness of the n⁻-type epitaxial layer 32, upper portions of the n-type current spreading region 23 are formed between the p⁺-type regions 22 that are adjacent to one another.

The upper portions of the p⁺-type regions 22 and the upper portion of the n-type current spreading region 23 are formed at positions facing, respectively in the depth direction, the lower portions of the p⁺-type regions 22 and the lower portion of the n-type current spreading region 23, at depths penetrating through the portion increasing the thickness of the n⁻-type epitaxial layer 32, and are connected, respectively, to the lower portions of the p⁺-type regions 22 and the lower portions of the n-type current spreading region 23. The portion of the n⁻-type epitaxial layer 32 closer to the n⁺-type starting substrate 31 than are the p⁺-type regions 21, 22 and the n-type current spreading region 23 constitutes the n⁻-type drift region 2.

Next, on the n⁻-type epitaxial layer 32, the p-type epitaxial layer 33 constituting the p-type base region 3 is epitaxially grown (deposited) having a thickness of, for example, about 1 μm. By the processes up to here, the semiconductor substrate (semiconductor wafer) 30 in which the epitaxial layers 32, 33 are sequentially stacked on the front surface of the n⁺-type starting substrate 31 is fabricated (manufactured) (first process). Next, by photolithography and ion implantation, the n⁺-type source regions 4 and the p⁺⁺-type contact regions 5 are each selectively formed in surface regions of the p-type epitaxial layer 33 (third process).

The portion of the p-type epitaxial layer 33 closer to the n⁻-type epitaxial layer 32 than are the n⁺-type source regions 4 and the p⁺⁺-type contact regions 5 constitutes the p-type base region 3. Next, the p-type impurity concentration profile 41 in the depth direction of the p-type base region 3 is adjusted by two or more stages of ion implantation performed to the p-type base region 3 from the front surface of the semiconductor substrate 30 (second process). In the two or more stages of ion implantation performed to the p-type base region 3, the depth positions of the respective ranges are within the p-type base region 3 and mutually different acceleration voltages are set while the dose amounts are set to be lower the higher is the corresponding acceleration voltage.

In the two or more stages (in FIG. 4, two stages) of the ion implantation performed to the p-type base region 3, the depth positions (in FIG. 4, the depth positions D1, D2) of the ranges are assumed as the deep positions closer to the n⁺-type drain region 1 the higher is the acceleration voltage of the stage of the ion implantation, and an ion implantation profile with a wide half width (in FIG. 4, the ion implantation profiles 61, 62) is formed. Any of the ion implantation profiles adjacent to one another in the depth direction and formed by the two or more stages of ion implantation performed to the p-type base region 3 may be adjacent to one another in the depth direction or may overlap one another in the depth direction.

Further, during the two or more stages of ion implantation performed to the p-type base region 3, as far as possible, no p-type impurity is ion-implanted into the n-type current spreading region 23. In other words, it is favorable for the ion implantation profile resulting from ion implantation to the p-type base region 3 to not reach the n-type current spreading region 23 and the ion implantation profile resulting from the ion implantation with the highest acceleration voltage performed to the p-type base region 3 (corresponds to the ion implantation profile 62 in FIG. 4), preferably, terminates at a border between the p-type epitaxial layer 33 and the n⁻-type epitaxial layer 32.

As described, the on-resistance is determined by the peak concentration in the ion implantation profile resulting from the ion implantation performed to the p-type base region 3 and having the lowest acceleration voltage (i.e., the peak concentration occurring closest to the n⁺-type source regions 4 in the p-type impurity concentration profile 41 in the depth direction of the p-type base region 3). The gate threshold voltage is determined by the impurity concentration of the portion closer to the n⁺-type drain region 1 than is the depth position (corresponds to the depth position D1 in FIG. 4) of the peak concentration occurring closest to the n⁺-type source regions 4 in the p-type impurity concentration profile 41 in the depth direction of the p-type base region 3.

Further, the p-type impurity concentration profile 41 in the depth direction of the p-type base region 3 gradually decreases from the depth position of the peak concentration occurring closest to the n⁺-type source regions 4, in a direction to the n⁺-type drain region 1. As a result, the impurity concentration of the portion closer to the n⁺-type drain region 1 than is the depth position of the peak concentration occurring closest to the n⁺-type source regions 4 in the p-type impurity concentration profile 41 in the depth direction of the p-type base region 3 is higher, as compared to the p-type impurity concentration profile 141 in the depth direction of the p-type base region 103 (refer to FIG. 3) of the conventional example.

While the sequence in which the two or more stages of ion implantation are performed to the p-type base region 3 may be changed as necessary, when ion implantation by a high acceleration voltage is performed after ion implantation with a low acceleration voltage, the impurity introduced by the ion implantation with the low acceleration voltage may be pushed to a deep portion of the semiconductor substrate 30 by the subsequent ion implantation with the high acceleration voltage. Therefore, sequentially performing the ion implantation from that with the higher acceleration voltage facilitates adjustment of the p-type impurity concentration profile 41 in the depth direction of the p-type base region 3 to the targeted p-type impurity concentration profile.

Further, the p-type base region 3 suffices to have the p-type impurity concentration profile 41 in the depth direction and instead of the p-type epitaxial layer 33, an n-type epitaxial layer may be deposited, and a p-type impurity may be introduced in a formation region for the p-type base region 3 in the n-type epitaxial layer by two or more stages of ion implantation so that the p-type impurity concentration profile 41 is formed. In this instance, in surface regions of the n-type epitaxial layer, the n⁺-type source regions 4 in contact with the p-type base region 3, and the p⁺⁺-type contact regions 5 are each selectively formed.

The sequence in which the adjustment (or formation) of the p-type impurity concentration profile 41 in the depth direction of the p-type base region 3, the formation of the n⁺-type source regions 4, and the formation of the p⁺⁺-type contact regions 5 are performed may be changed as necessary. Next, a heat treatment for activating all the ion-implanted impurities is performed. Next, by a general method, the trenches 6, the gate insulating films 7, the gate electrodes 8, the interlayer insulating film 9, the source electrode 11, and the drain electrode 12 are formed (fourth, fifth, sixth, and seventh processes). Thereafter, the semiconductor wafer (the semiconductor substrate 30) is diced (cut) into individual chips, whereby the semiconductor device 10 depicted in FIG. 1 is completed.

As described above, according to the embodiment, the p-type impurity profile in the depth direction of the p-type base region is adjusted by two or more stages of ion implantation, and gradually decreases from the depth position of the peak concentration occurring closest to the n⁺-type source regions, in a direction to the n⁺-type drain region. The internal resistance of a portion of the p-type base region close to the n⁺-type drain region is reduced by ion implantation with a high acceleration voltage and thus, even when the impurity concentration of the portion of the p-type base region close to the n⁺-type drain region is increased and the gate threshold voltage is increased, the on-resistance does not increase. Alternatively, the on-resistance may be reduced while maintaining the gate threshold voltage as it is. Thus, the tradeoff relationship in which the on-resistance decreases when the gate threshold voltage is increased may be improved.

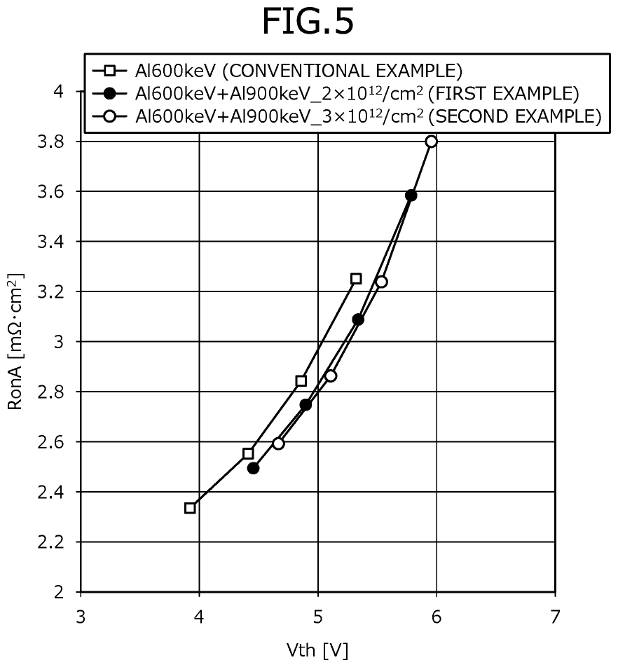

The relationship between the gate threshold voltage and the on-resistance of the semiconductor device 10 according to the embodiment was verified. FIG. 5 is a characteristics diagram depicting the relationship between the gate threshold voltage and the on-resistance of the first and second examples. In FIG. 5, a horizontal axis is the gate threshold voltage Vth [V] while a vertical axis is the on-resistance RonA [mΩ⋅cm²]. The relationships between the gate threshold voltage Vth and the on-resistance RonA for the first and second examples and the conventional example described above are depicted in FIG. 5.

From the results depicted in FIG. 5, it was confirmed that when the same on-resistance RonA as that in the conventional example is set in the first and second examples, the gate threshold voltage Vth may be increased to be higher than that in the conventional example. It was confirmed that alternatively, when the gate threshold voltage Vth is that same as that in the conventional example, variation of the gate threshold voltage Vth with respect to the targeted gate threshold voltage value may be maintained to about that in the conventional example while the on-resistance RonA may be reduced more than that in the conventional example.

Thus, it was confirmed that, as described above, the p-type impurity concentration profile 41 in the depth direction of the p-type base region 3 is adjusted (refer to FIG. 3), whereby the tradeoff relationship in which the on-resistance RonA decreases when the gate threshold voltage Vth is increased may be improved. Therefore, the vertical SiC-MOSFET having a trench gate structure may be structured such that, even when the gate threshold voltage Vth is increased, the on-resistance does not increase.

In the foregoing, the present invention may be variously changed and in the described embodiments, for example, dimensions, impurity concentrations, etc. of regions, and the like may be variously set according to necessary specifications. Further, in the embodiments, while a first conductivity type is assumed to be an n-type and a second conductivity type is assumed to be a p-type, the present invention is similarly implemented when the first conductivity type is a p-type and the second conductivity type is an n-type.

According to the described invention, the internal resistance of a portion of the second semiconductor region (the portion facing the second main surface) decreases and therefore, even when the impurity concentration of said portion of the second semiconductor region facing the second main surface is increased and the gate threshold voltage is increased, the on-resistance does not increase.

Alternatively, the on-resistance may be reduced while maintaining the gate threshold voltage as it is.

The semiconductor device and the method of manufacturing a semiconductor device according to the present invention achieve an effect in that the tradeoff relationship in which the on-resistance decreases when the gate threshold voltage is increased may be improved.

As described, the semiconductor device and the method of manufacturing a semiconductor device according to present invention are useful for power semiconductor devices used in power converting equipment, power source devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate containing silicon carbide and having a first main surface and a second main surface opposite to each other;
a first semiconductor region of a first conductivity type, provided in the semiconductor substrate;
a second semiconductor region of a second conductivity type, provided between the first main surface of the semiconductor substrate and the first semiconductor region;
a third semiconductor region of the first conductivity type, selectively provided between the first main surface of the semiconductor substrate and the second semiconductor region;
a trench penetrating through the third semiconductor region and the second semiconductor region, and reaching the first semiconductor region;
a gate electrode provided in the trench via a gate insulating film;
a first electrode electrically connected to the second semiconductor region and the third semiconductor region; and
a second electrode provided at the second main surface of the semiconductor substrate, wherein
the second semiconductor region has an impurity concentration profile in a depth direction from the first main surface to the second main surface, and
in the impurity concentration profile:
an impurity concentration of the second semiconductor region decreases by a first gradient in the depth direction from a first depth position of a highest impurity concentration to the first main surface,
the impurity concentration decreases monotonically in the depth direction from the first depth position to the second main surface and the impurity concentration profile exhibits a step-shaped curve at one or more different second depth positions closer to the second main surface than is the first depth position, and
the impurity concentration, from the first depth position to the one or more different second depth positions, decreases by a second gradient that is more gradual than the first gradient.

2. The semiconductor device according to claim 1, wherein
in the impurity concentration profile of the second semiconductor region, between a first one of the one or more different second depth positions and the first depth position or a second one of the one or more different second depth positions adjacent to the first one and closer to the first main surface than is the first one, the impurity concentration in the depth direction to the second main surface, decreases by a gradient resulting in a curve convex in a direction that the impurity concentration increases, or the impurity concentration is uniform.

3. The semiconductor device according to claim 1, wherein
in the impurity concentration profile of the second semiconductor region, a distance between a first one of the one or more different second depth positions and the first depth position or a second one of the one or more different second depth positions adjacent to the first one and closer to the first main surface than is the first one is in a range of 0.1 μm to 0.2 μm.

4. The semiconductor device according to claim 1, wherein
the impurity concentration of the second semiconductor region, in a portion from the first depth position to a third depth position that is 0.2 μm in a direction to the second main surface, is at least 1/10 of the impurity concentration at the first depth position.

5. The semiconductor device according to claim 1, wherein
the first depth position is closer to the first main surface than is a center of the second semiconductor region in the depth direction.

6. The semiconductor device according to claim 1, wherein
the impurity concentration of the second semiconductor region is in a range of 4.0×10¹⁷/cm³ to 8.0×10¹⁷/cm³ at the first depth position.

7. The semiconductor device according to claim 1, further comprising:
a first high-concentration region of the second conductivity type, selectively provided in the semiconductor substrate, closer to the second main surface than is a bottom of the trench and apart from the second semiconductor region, the first high-concentration region facing the bottom of the trench in the depth direction and having an impurity concentration that is higher than the impurity concentration of the second semiconductor region; and
a second high-concentration region of the second conductivity type, selectively provided in the semiconductor substrate, closer to the second main surface than is the bottom of the trench, the second high-concentration region being in contact with the second semiconductor region and apart from the trench and the first high-concentration region, the second high-concentration region having an impurity concentration that is higher than the impurity concentration of the second semiconductor region.

8. A method of manufacturing a semiconductor device, the method comprising:
as a first process, fabricating a semiconductor substrate having a first semiconductor region of a first conductivity type in a silicon carbide layer, the fabricating including preparing a starting substrate containing silicon carbide and epitaxially growing the silicon carbide layer on the starting substrate, a surface of the silicon carbide layer constituting a first main surface of the semiconductor substrate and a surface of the starting substrate constituting a second main surface of the semiconductor substrate;
as a second process, forming a second semiconductor region of a second conductivity type in the silicon carbide layer, between the first main surface and the first semiconductor region;
as a third process, selectively forming a third semiconductor region of the first conductivity type in the silicon carbide layer, between the first main surface and the second semiconductor region;
as a fourth process, forming a trench that penetrates through the third semiconductor region and the second semiconductor region, the trench reaching the first semiconductor region;
as a fifth process, forming a gate electrode in the trench via a gate insulating film;
as a sixth process, forming a first electrode electrically connected to the second semiconductor region and the third semiconductor region; and
as a seventh process, forming a second electrode at the second main surface, wherein
the forming the second semiconductor region includes introducing from the first main surface to the silicon carbide layer, impurity ions of the second conductivity type into the second semiconductor region by performing a plurality of ion implantations, including a first ion implantation and a second ion implantation, in the plurality of ion implantations, an acceleration voltage thereof and a dose amount thereof are set such that the acceleration voltage increases as the dose amount decreases, while a depth position of the impurity ions of each ion implantation is maintained within the second semiconductor region, whereby an impurity concentration profile in the second semiconductor region in a depth direction from the first main surface to the second main surface is formed such that:
the impurity concentration decreases in the depth direction by a first gradient from a first depth position of a highest impurity concentration to the first main surface, and
the impurity concentration decreases monotonically from the first depth position in the depth direction to the second main surface, forming a step at one or more different second depth positions that are closer to the second main surface than is the first depth position, and the impurity concentration decreases from the first depth position to the one or more different second depth positions by a second gradient that is more gradual than the first gradient.

9. The method according to claim 8, wherein
the forming the second semiconductor region includes setting a first acceleration voltage of the first ion implantation to be in a range of 1.3 times to 1.6 times a second acceleration voltage of the second ion implantation, the second acceleration voltage being next lower than the first acceleration voltage among acceleration voltages respectively used in the multiple times of ion implantation.

10. The method according to claim 8, wherein
the forming the second semiconductor region includes setting a first dose amount of the first ion implantation to be in a range of 10% to 20% of a second dose amount of the second ion implantation, the second ion implantation having a second acceleration voltage that is next lower than a first acceleration voltage of the first ion implantation.

11. The method according to claim 8, wherein
the fabricating the semiconductor substrate includes sequentially depositing as the silicon carbide layer, a first-conductivity-type silicon carbide layer constituting the first semiconductor region and a second-conductivity-type silicon carbide layer, and
the forming the second semiconductor region includes performing the multiple times of ion implantation so as to adjust a portion of the second-conductivity-type silicon carbide layer to the impurity concentration profile, the adjusted portion excluding the third semiconductor region and constituting the second semiconductor region.

12. The method according to claim 8, wherein
the fabricating the semiconductor substrate includes depositing the silicon carbide layer of a first conductivity type, and
the forming the second semiconductor region includes performing the multiple times of ion implantation so that the depth position of the impurity ions implanted thereby is between the third semiconductor region and the first semiconductor region of the silicon carbide layer, thereby forming the second semiconductor region having the impurity concentration profile.
